(19) United States
(12) Patent Application Publication
(10) Pub. No.: US 2003/0001174 A1
(43) Pub. Date: Jan. 2, 2003

(54) Modulation semiconductor integrated circuit device and electronic system

(75) Inventors: Takaaki Henmi, Musashino (JP); Masaru Kokubo, Hannou (JP)

Correspondence Address: Stanley P. Fisher, Reed Smith Hazel LLP, 3110 Fairview Park Drive, Suite 1400, Falls Church, VA, 22042-4503, US

(73) Assignee: Hitachi, Ltd.

(21) Appl. No.: 10/142,987

(22) Filed: May 13, 2002

(30) Foreign Application Priority Data
Jun. 29, 2001 (JP) 2001-197714

(51) Int. Cl. H01L 29/80

(52) U.S. Cl. 257/275

(57) ABSTRACT

A filter that can achieve miniaturization and low power consumption at the same time without reducing operation precision, and a modulation semiconductor integrated circuit suitable for a wireless communication system using the filter are realized. In a modulation semiconductor integrated circuit including a digital filter that sample a digital transmission data signal an odd number of times for each two symbol cycles to perform product-sum operations, and a DA conversion circuit that subjects the output of the digital filter to DA conversion, a compensating circuit is provided which inserts predetermined values different from two types of symbols to the input of the digital filter.

### BACKGROUND OF THE INVENTION

The present invention relates to technology effectively applied to miniaturization of a digital filter circuit, particularly a FIR-(Finite Impulse Response) filter, and technology effectively used for a Gauss filter provided in a transmission system of a wireless communication system such as, e.g., Bluetooth.

A wireless communication LSI (large-scale semiconductor integrated circuit) is developed with the greatest emphasis on low power consumption and miniaturization, particularly with LSI used for carriage. By the way, a wireless communication system, which processes analog signals, requires the introduction of a filter for which miniaturization and low power consumption are also demanded. On the other hand, with the advance of digital communication technology, digital filters are increasingly adopted in a wireless communication system.

Digital filters are classified as FIR filters not subjected to feedback and IIR (Infinite Impulse Response) filters subjected to feedback. FIG. 12 shows a basic configuration of a digital FIR filter. As shown in the drawing, a digital FIR filter comprises an input register part REG that gets input data, and a product-sum operation part MAC that multiplies the got input data by filter coefficients and sums the results. The filter coefficients multiplied by the input data are generally referred to as tap coefficients and the number of stages of the register part is referred to as tap length.

In the case of a general digital FIR filter, the logical scale of circuit depends on tap length, a quantization number of tap coefficients, and the number of bits handled by a product-sum computing unit. Filter power consumption depends on the logical scale of a circuit and a sampling frequency of input data. Therefore, making the values of these parameters as small as possible is a key factor for achieving the miniaturization and low power consumption of the digital filter. However, making the values of these parameters small reduces filter precision.

### SUMMARY OF THE INVENTION

As conventional technology for miniaturizing a digital FIR filter, for example, there is proposed the invention that performs sampling at a frequency N times an operating frequency and performs product-sum operations on individual tap coefficients in time-sharing mode to thereby reduce the number of product-sum computing units (Japanese Published Unexamined Patent Application No. 2000-40942). However, the prior invention has a problem in that the number of product-sum computing units can be reduced without reducing operation precision but power consumption cannot be reduced because of an increased sampling frequency.

Accordingly, the inventor et al. contemplated reducing a sampling frequency and reducing the tap length of a digital FIR filter, that is, the number of stages for getting input data.

To reduce a sampling frequency, it is divided by the n-th power of 2 such as half frequency division, quarter frequency division, and so forth. This is a technique of easiest minimizing an increase in a logical circuit.

Where a sampling count for input data is odd, further frequency-dividing it by two corresponds to the case of performing sampling an odd number of times per two symbol cycle. The present invention describes a technique effective for such a case. An example of this occurs when a 13-MHz sampling frequency used under the GSM (Global System for Mobile Communication) standard is halved to 6.5 MHz. Where Bluetooth is adopted for GSM, since a clock generally operates based on 13 MHz, which is the same as the frequency of a source clock of the GSM system (shares the crystal oscillator of the source clock), we contemplated finding a tap count and tap quantization number complying with the Bluetooth standard for a sampling frequency of 6.5 MHz, which is half the frequency of 13-MHz clock.

As a result of conducting a study of the existence of a possible solution of tap length of an FIR filter satisfying specifications of a transmission system of Bluetooth regarding the above 6.5-MHz sampling frequency, we learned that specifications of transmission power can be satisfied depending on tap count and bit quantization even if the sampling frequency of the digital FIR filter is 6.5 MHz. However, there was a problem in that the above digital FIR filter configuration caused a deviation in a carrier frequency.

In characteristics called an eye pattern (reflecting the accuracy of evaluation of whether receive data is “1” or “0”), there occurred the phenomenon that eye aperture changing depending on the magnitude of waveform distortion deteriorated remarkably. As a result of pursuit for the cause of it, it was found that there was a bias in data sampling count within any two symbols and the bias caused an apparent central position of filter output to deviate from 0.

The eye pattern is a pattern as shown in FIG. 13(B) appearing when signals of one symbol cycle each representing 1-bit data are extracted for each two symbol cycle and superimposed on one another when a data string of +1 and −1 as shown in FIG. 13(A) is transmitted. An eye aperture is a value represented by Δf2/Δf1, where Δf1 is a displacement amount from a center during continuous transmission of +1 or −1 in the eye pattern, and Δf2 is a displacement amount at peak when data changes from +1 to −1 or from +1 to −1.

FIG. 13 shows, as one example, a case where, for a 2.4-GHz carrier frequency, data +1 is transmitted with a signal with the carrier frequency subjected to frequency modulation by plus 160 kHz, and data −1 is transmitted with a signal with the carrier frequency subjected to frequency modulation by minus 160 kHz. Representation by an eye pattern is not limited to such a case but is widely used in the field of wireless communications using frequency modulation.

The present invention has been made to solve the above problems and its object is to provide a filter that can achieve miniaturization and low power consumption at the same time without reducing operation precision, and a modulation semiconductor integrated circuit suitable for a wireless communication system using the filter.

Another object of the present invention is to provide a small-scale and low-power-consumption wireless communication system suitable for cellular electronic equipment.

The foregoing and other objects and novel characteristics of the present invention will become apparent from the foregoing description of the specifications and the accompanying drawings.

Typical ones of inventions disclosed in this patent application will be outlined below.

In a modulation semiconductor integrated circuit including a digital filter that samples a digital transmission data signal an odd number of times for each two symbol cycles to perform predetermined operations, and a DA conversion circuit that subjects the output of the digital filter to DA conversion, a compensating circuit is provided which inserts predetermined values different from two types of symbols to the input of the digital filter.

According to the above described means, data can be sampled without bias and an apparent center of filter outputs can be positioned in the vicinity of 0. Thereby, eye aperture can be increased and the extent of frequency variations can be reduced.

Preferably, the compensating circuit samples input data signals at a frequency N times a sampling frequency of the digital filter and outputs the average of two values sampled before and after. Thereby, addition of a relatively simple circuit enables predetermined values different from two types of symbols to be inserted to the input of digital filter. N is an integer of 2 or greater.

Furthermore, preferably, the compensating circuit comprises a delay means that samples input data signals at a frequency N times a sampling frequency of the digital filter and provides a delay of one cycle, an adder that adds a signal delayed by the delay means and an input signal at that time, an operation means that halves the output of the adder, and a delay means for bringing an output of the operation means into line with the sampling frequency of the digital filter. Thereby, as predetermined values inputted to the digital filter, the average value of two types of symbols can be created and inserted.

The digital filter comprises an input shift register that successively samples and shifts outputs of the compensating circuit, plural first means that output a value corresponding to the product of data held at each stage of the register and a predetermined filter coefficient, and plural second means that successively add outputs of the first means and outputs the added value. Thereby, existing digital FIR filters can be used, facilitating a circuit design.

Furthermore, the number of stages of the digital filter is seven. Thereby, the number of stages of a register can be reduced, so that a filter that can achieve miniaturization and low power consumption at the same time, and a modulation semiconductor integrated circuit suitable for a wireless communications using the filter are realized.

The filter coefficients are 5 bits. Thereby, the scale of an operation means to perform operations between input data and the filter coefficients can be reduced, so that a filter that can achieve miniaturization and low power consumption at the same time, and a modulation semiconductor integrated circuit suitable for a wireless communications using the filter are realized.

Furthermore, there is provided an oscillating circuit whose oscillation frequency is controlled by the output of the DA conversion circuit for the output of a digital FIR filter. Thereby, a modulation semiconductor integrated circuit of the frequency modulation system can be realized which subjects an input data signal to frequency modulation and outputs a resulting signal.

Also, preferably, in the case where a 2.4-GHz oscillation signal is used as a carrier frequency signal and outputted after frequency modulation in a range of ±160 kHz by an input data signal, a sampling frequency of the digital filter is set at 6.5 MHz. Thereby, circuits satisfying conditions defined under the Bluetooth standard can be brought into miniaturization and low power consumption.

Furthermore, an electronic system according to the present invention comprises a modulation semiconductor integrated circuit configured as described above, a wireless communication means that converts signals to digital data and modulates the digital data for wireless communications, and a crystal oscillating circuit that generates a clock signal required for operation of the wireless communication means, wherein a clock signal generated derivatively from a clock signal generated by the crystal oscillating circuit is used as a sampling clock of the digital filter. Thereby, the sharing of the crystal oscillating circuit can be achieved, contributing to reduction in system costs.

The wireless communication means may comprise a base band circuit that converts signals to digital data signals suitable for wireless communications, and a high-frequency modulation circuit that modulates digital data signals from the base band circuit to high-frequency signals and outputs the high-frequency signals, wherein a clock signal generated in the crystal oscillating circuit is supplied to the high-frequency modulation circuit and a clock signal whose frequency is halved by the high-frequency modulation circuit is supplied to the base band circuit and the modulation semiconductor integrated circuit. Also in this way, the sharing of the crystal oscillating circuit can be achieved and system costs can be reduced, while existing high-frequency modulation circuits can be used to inexpensively provide electronic equipment such as cellular telephones having wireless communication functions defined under, e.g., the Bluetooth standard.

### BRIEF DESCRIPTION OF THE DRAWINGS

FIG. 1 is a block diagram showing the configuration of a wireless communication system suitably using a modulation semiconductor integrated circuit of the present invention;

FIG. 2 is a block diagram showing an embodiment of a digital FIR filter used in a modulation semiconductor integrated circuit of the present invention;

FIG. 3 is a conceptual diagram showing a digital FIR filter used in an embodiment;

FIGS. 4(A) to 4(F) show timing chart of one example of operation timing of a digital FIR filter provided with an offset compensating circuit of an embodiment;

FIGS. 5(A) to 5(F) show a timing chart of other operation timing of a digital FIR filter provided with an offset compensating circuit of an embodiment;

FIGS. 6(A) to 6(D) show a timing chart of operation timing of a conventional digital FIR filter not having an offset compensating circuit;

FIGS. 7(A) to 7(D) show a timing chart of other operation timing of a conventional digital FIR filter not having an offset compensating circuit;

FIGS. 8(A) and 8(B) are waveform diagrams showing an eye pattern of a conventional digital FIR filter not having an offset compensating circuit and an eye pattern of a digital FIR filter of an embodiment;

FIG. 9 is a frequency characteristic diagram showing the specification of transmission power in the Bluetooth standard to which the present invention is suitably applied;

FIGS. 10(A) and 10(B) are conceptual diagrams showing a configuration of multipliers of input data and filter coefficients used in a digital FIR filter of an embodiment;

FIG. 11 is a block diagram showing an overall configuration of a cellular telephone to which the wireless communication LSI of the embodiment is applied;

FIG. 12 is a block diagram showing a configuration of a conventional FIR filter;

FIGS. 13(A) and 13(B) are waveform diagrams showing a transmission data string and an eye pattern in communications of the Bluetooth standard.

### DETAILED DESCRIPTION OF THE PREFERRED EMBODIMENTS

Hereinafter, preferred embodiments of the present invention will be described with reference to the accompanying drawings.

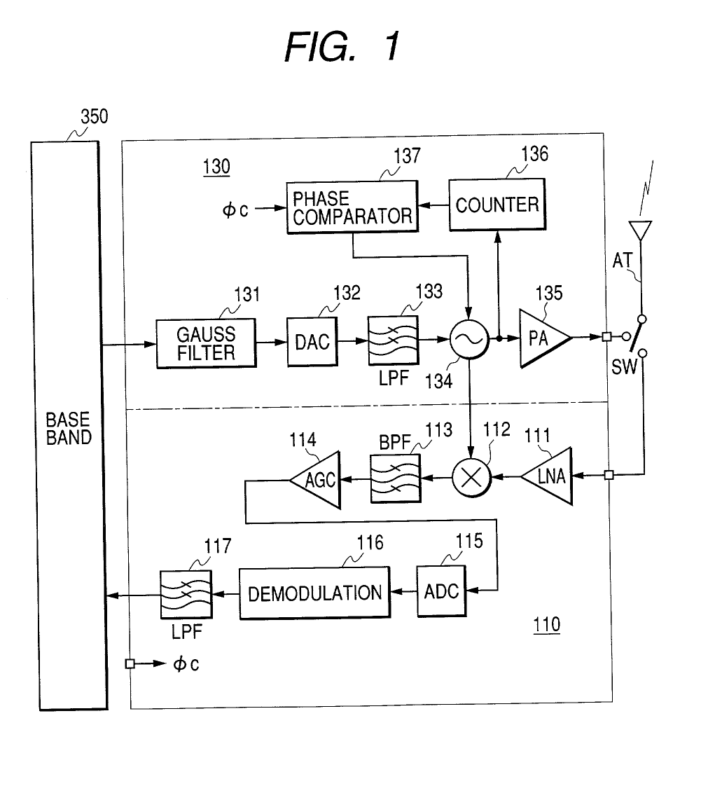

FIG. 1 shows a configuration of a wireless communication system suitably using a modulation semiconductor integrated circuit of the present invention.

In FIG. 1, AT designates a transmitting/receiving antenna for signal radio waves; SW, a switch for switching between transmission and reception; 110, a receiving circuit that down-converts a signal received from the antenna AT into an intermediate frequency before amplifying and demodulating it, and converts it into a base band signal; and 130, a transmitting circuit that modulates a base band signal transmitted from the antenna AT for frequency conversion.

The transmitting circuit 130 comprises: a Gauss filter 131 that samples an input rectangular wave signal and generates code for modulation; a DA conversion circuit 132 that performs DA conversion for the output of the filter to generate a signal of stepped waveform; a low pass filter 133 that turns the generated signal of stepped waveform into a smooth waveform; a frequency conversion circuit 134, composed of a voltage control oscillating circuit (VCO), that performs modulation by an oscillation frequency being controlled by an output voltage of the low pass filter 133; and a power amplifier 135 that amplifies a signal subjected to frequency conversion to such an extent as to correspond to transmission power to transmit the signal.

Moreover, the transmitting circuit 130 of this embodiment is provided with a counter 136 that frequency-divides the output of the VCO 134, and a phase comparator 137 that compares the phase of output of the counter 136 and the phase of reference clock φc such as e.g., 13 MHz and generates voltage corresponding to a phase difference to control the oscillation frequency of the VCO 134. A PLL circuit is formed by the VCO 134, the counter 136, and the phase comparator 137 and produces a carrier frequency. A control voltage to the VCO 134 is changed by an output voltage of the low pass filter 133 reflecting transmit data, whereby an oscillation frequency signal is modulated.

In the wireless communication system of this embodiment, a carrier frequency can be made variable by changing a count value counted by the counter 136 according to a command from the base band circuit 350. The carrier frequency can be shifted in units of, e.g., 1 MHz (made variable) so that spread spectrum data transmission based on so-called frequency hopping can be performed.

The receiving circuit 110 comprises: a low-noise amplifier (LNA) 111 that amplifies a signal received from the antenna AT; a mixer (MIX) 112 that down-converts an amplified receive signal into a signal of an intermediate frequency (e.g., 2 MHz) by synthesizing the amplified receive signal and an oscillation signal from the VCO of the transmission side; a bandpass 113 that eliminates a leak signal from an adjacent channel to extract a signal component of the channel; a gain-controllable programmable gain amplifier (AGC) 114 that amplifies a signal to a proper amplitude; an AD conversion circuit 115 that converts an analog signal to a digital signal; a demodulating circuit 116 that demodulates receive data; and a low pass filter (LPF) 117 that eliminates high-frequency components (noise) from a demodulated signal and passes receive data to the base band circuit 350.

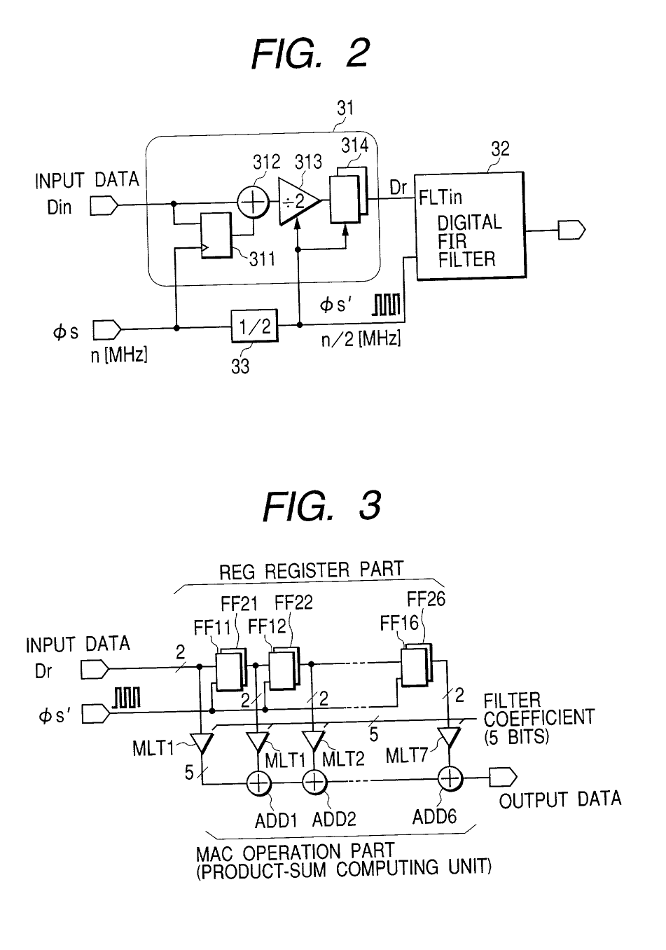

FIG. 2 shows an embodiment of a digital FIR filter used as a Gauss filter 131 constituting the transmitting circuit 130. In the filter of this embodiment, as shown in FIG. 2, a frequency offset compensating circuit 31 is provided at a stage preceding the digital FIR filter 32, signals that brought 311 and 312 of the frequency offset compensating circuit 31 into operation by an input sampling clock φs are reoutputted by an input sampling clock φs/2 of the digital FIR filter, input data is compensated by the frequency offset compensating circuit 31 and inputted to the digital FIR filter 32, and the digital FIR filter 32 is brought into operation by a clock φs′ produced by halving the frequency of the input sampling clock φs by the frequency divider 33.

The frequency offset compensating circuit 31 comprises: a delay circuit 311 composed of a D type flip-flop that latches input data synchronously with a rising edge or falling edge of an input sampling clock φs; an adder 312 that adds one-cycle-old input data delayed by the delay circuit 311 and current input data; a divider 313 that halves an added value; and a delay means 314 that brings the output of the divider into line with a sampling cycle of the filter in a following stage. A 2-bit signal Dr indicating that the output of the divider 313 is “1”, “−1”, or “0” designating ½ is inputted to the digital FIR filter 32.

On the other hand, the digital FIR filter used in this embodiment comprises: as shown in FIG. 3, an input register part REG formed by two shift registers with the respective six flip-flops FF11 to FF16, and FF21 to FF26 connected in series; and a product-sum operation part MAC that comprises seven multipliers MLT1 to MLT7 performing multiplication with filter coefficients correspondingly to the flip-flops FF11, FF12 to FF16, and FF26 of the different stages, and adders ADD1 to ADD6 successively summing the outputs of the multipliers MLT1, MLT2, . . . MLT7.

The filter coefficients are signed tap coefficients consisting 5 bits in this embodiment, one of which is used as a positive or negative sign. Multiplying a positive filter coefficient and input data increases operation results, and multiplying a negative filter coefficient and input data decreases operation results. Thereby, subjecting filter outputs to DA conversion results in a stepped waveform being produced.

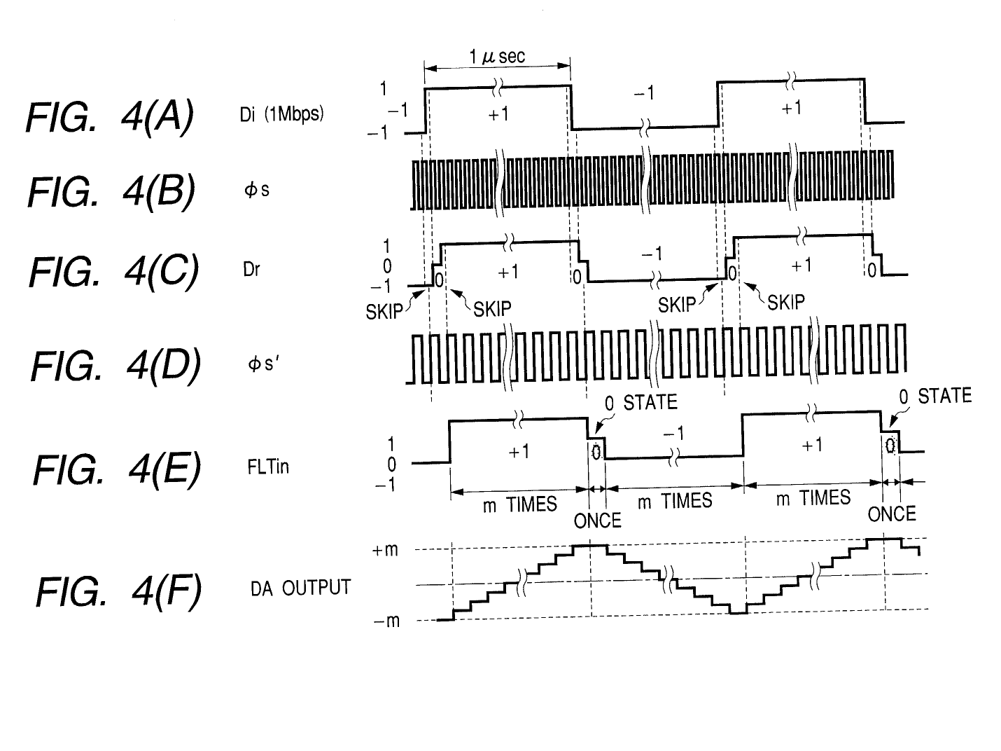

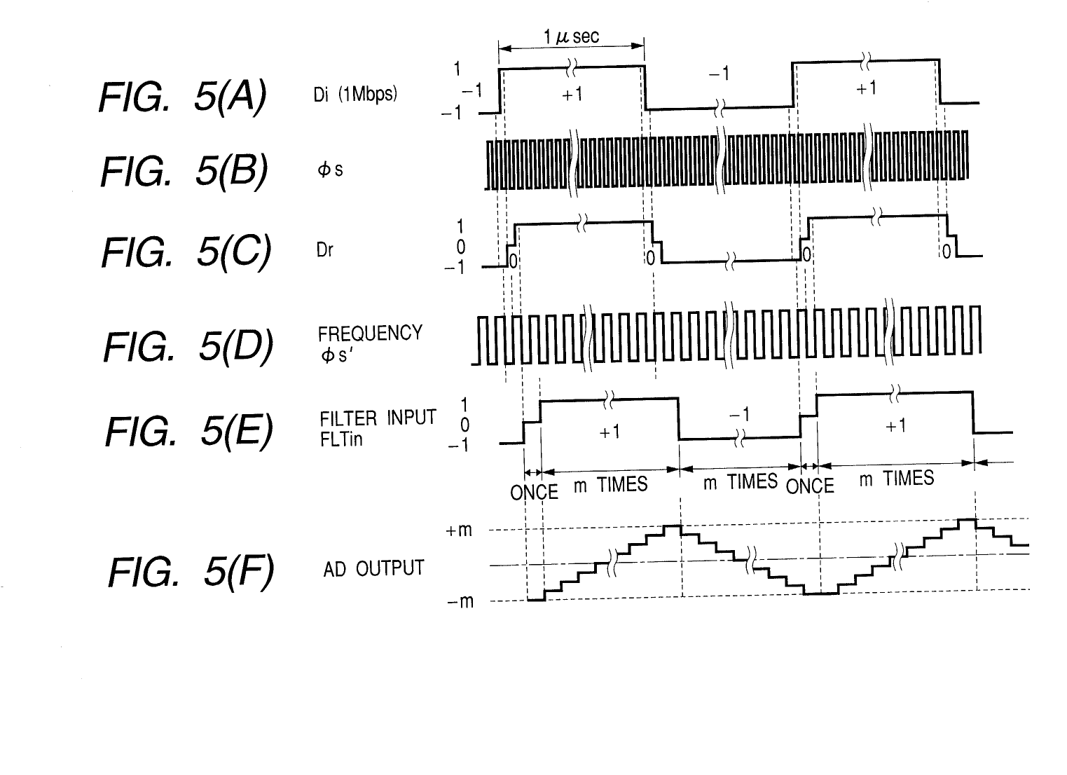

FIG. 4 shows an operation timing chart of the frequency offset compensating circuit 31. In FIG. 4, (A) designates input Din; (B), a sampling clock φs such as, e.g., 13 MHz; (C), output Dr of the frequency offset compensating circuit 31; (D), a frequency dividing clock φs′ such as, e.g., 6.5 MHz; and (E), a substantial input waveform to the digital FIR filter 32. φs′=φs/2. If φs is odd, φs=φs/2 corresponds to the case where sampling is performed an odd number of times within two symbols.

Consider the case where, for a digital FIR filter of tap length n, a sampling frequency φs in FIG. 4(B) is equal to 2 m+1 (m is a nonzero integer), where m<n.

If, as shown in FIG. 4(A), input data Din (e.g., 1/1 Mbps data in Bluetooth) changing to +1 or −1 with data width 1 μs (transfer speed 1 Mbps) is captured into the frequency offset compensating circuit 31 at a sampling clock φs of 13 MHz of FIG. 4(B) to perform compensation operation, as shown in FIG. 4(C), a value of 0, which is the average of the input data, is outputted at change points from −1 to +1 and from +1 to −1 from the frequency offset compensating circuit 31.

If the output values of the frequency offset compensating circuit 31 are captured into the digital FIR filter 32 at a clock φs′ of FIG. 4(D) produced by halving the frequency of the sampling clock φs, a substantial input waveform FLTin of the digital FIR filter 32 takes such a form that, as shown in FIG. 4(E), +1 and −1 each continue at an identical cycle (m), and when data changes from “+1” to “−1”, the data becomes “0” for only one cycle of φs′. It is understood from this that there occurs no bias between capturing of input data +1 to the digital FIR filter 32 and capturing of −1.

FIG. 4 shows a timing in which the output “0” of the frequency offset compensating circuit 31 is captured into the filter when data changes from “+” to “−”. Depending on a positional relationship between (B) and (D), as shown in FIG. 5(E), when data changes from “−1” to “+1”, the output “0” of the frequency offset compensating circuit 31 may be captured into the filter. However, such operation continues when note is taken of a certain short time. Also in this case, there occurs no bias between capturing of input data +1 to the digital FIR filter 32 and capturing of −1.

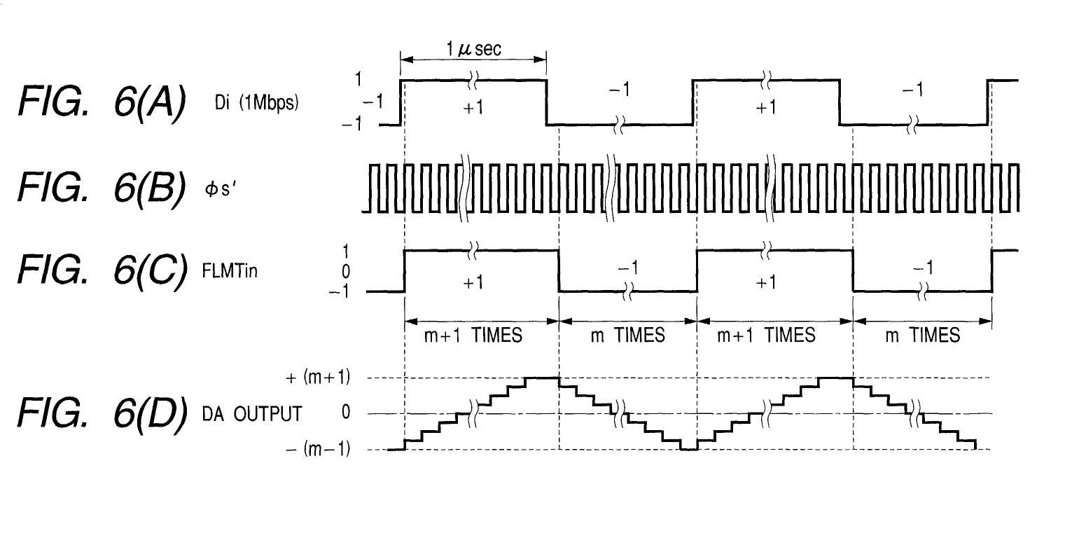

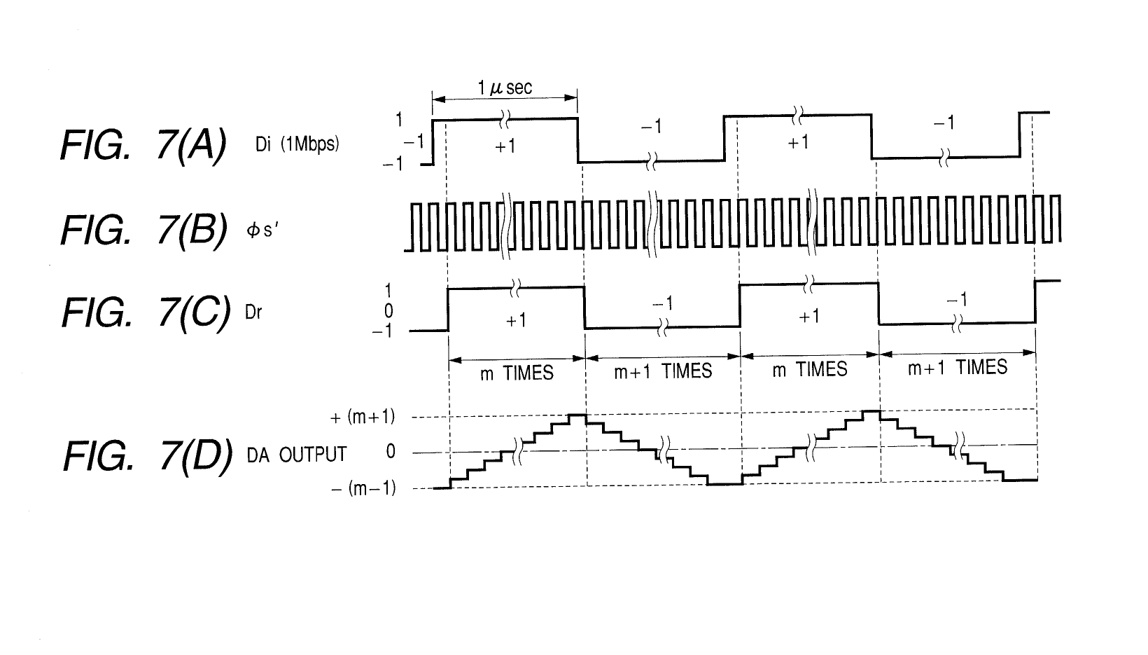

On the other hand, in the case where the frequency offset compensating circuit 31 is not provided, if input data Din changing to +1 or −1 with data width 1 μs (transfer speed 1 Mbps) were captured into the digital FIR filter 32 at a sampling clock φs′ (=φs/2) of 6.5 MHz, within a certain short time, there would occur a case as shown in FIG. 6(C) where data “+1” is captured for m+1 cycles and data “−1” is captured for m cycles, and a case shown in FIG. 7(C) where data “+1” is captured for m cycles and data “−1” is captured for m+1 cycles.

In such a case, an output waveform of the DA converter 132 subjecting the output of the digital FIR filter 32 to DA conversion shifts to the plus side on the whole in the case of FIG. 6 in which “+1” is captured more frequently. In other words, an output waveform of the DA converter becomes, as shown in FIG. 6(D), a stepped waveform like a sine wave with a maximum value MAX (m+1), a minimum value MIN −(m−1), and an apparent center position shifted to the plus side. In other words, an output waveform of the DA converter becomes, as shown in FIG. 7(D), a stepped waveform like a sine wave with a maximum value MAX (m−1), a minimum value MIN −(m+1), and an apparent center position shifted to the minus side. Where the digital FIR filter 32 continues to capture “+1” or “−1”, its output value does not continue to rise or fall; the filter coefficients are set so that the output value becomes saturated in a maximum value corresponding to +160 kHz or −160 kHz as shown in FIG. 6(D) or 7(D).

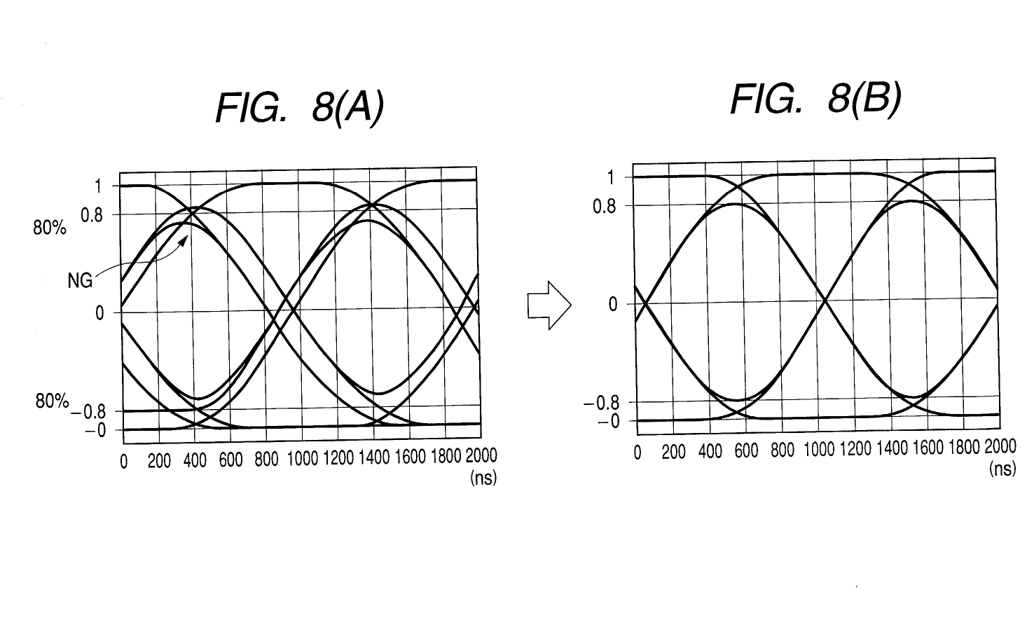

On the other hand, in the case where the frequency offset compensating circuit 31 is provided as in this embodiment, since there occurs no bias between capturing of +1 and capturing of −1 of input data to the digital FIR filter 32 as described previously, an output waveform of the DA converter becomes, as shown in FIG. 4(F) or FIG. 5(F), a stepped waveform like a sine wave with a maximum value MAX m, a minimum value MIN −m, and an apparent center position “0”. As a result, for a certain parameter of the digital FIR filter, where the frequency offset compensating circuit 31 is not provided, an eye pattern deteriorates with an aperture below 80% as shown in FIG. 8(A), while, where the frequency offset compensating circuit 31 is provided, with an aperture improved to 80% or more, an eye pattern is formed as shown in FIG. 8 (B). It is therefore understood that it is effective to provide the frequency offset compensating circuit 31. The output of the frequency offset compensating circuit 31 consists of 2 bits to discriminate among “+1”, “−1”, and “0”.

Next, a description will be made of a sampling frequency, tap length, and the number of bits of filter coefficients of the digital FIR filter 32 of this embodiment.

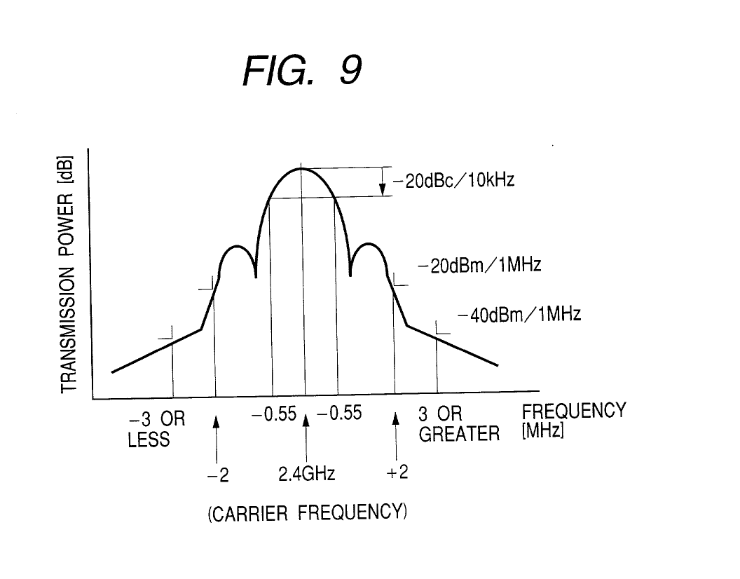

The Bluetooth standard dictates the following three conditions on transmission power: (1) relative attenuation at ±0.55 MHz (=550 kHZ) with respect to a carrier frequency (e.g., 2.4 GHz) is −20 dB/0.1 MHz or more as shown in FIG. 9; (2) absolute attenuation at ±2 MHz with respect to a carrier frequency 2.4 GHz is −20 dB/1 MHz or more; and (3) absolute attenuation at ±3 MHz with respect to a carrier frequency 2.4 GHz is −40 dB/1 MHz or more. This is because the Bluetooth standard adopts, as a transmission method, the spread spectrum method based on frequency hopping in units of 1 MHz in a frequency band of 2.4 to 2.48 GHz to prevent interference with signals in adjacent frequency bands.

To satisfy the above described conditions defined in the Bluetooth standard on transmission power, a study was conducted of requirements for the Gauss filter 131 in the transmission system 130 as shown in FIG. 1.

First, a sampling frequency of the Gauss filter was selected from 26, 13, 6.5, and 3.25 MHz. This is because, since the GSM (Global System for Mobile Communication) standard adopts a 13-MHz frequency clock, it is easy to unify clock frequencies when configuring a combined system of the GSM standard and the Bluetooth standard. By the way, as described previously, lower sampling frequencies contribute to reduction in power consumption. Accordingly, in this embodiment, 6.5 MHz was selected as a sampling frequency of the Gauss filter.

Next, for tap length and filter coefficients (tap coefficients), a study was conducted of values that satisfy the above described conditions and are effective for circuit miniaturization. Shorter tap length contributes to smaller circuit scale and reduction in power consumption. Accordingly, in this embodiment, tap length was set at 7.

Smaller tap coefficients contribute to smaller circuit scale and reduction in power consumption. Accordingly, in this embodiment, tap coefficients were decided as 5 bits. Since tap coefficients were set at 5 bits, the number of bits of the DA conversion circuit was also set at 5 bits. Therefore, for the Gauss filter of this embodiment, a sampling frequency is set at 6.5 MHz, tap length at 7 taps, and tap coefficients at 5 bits.

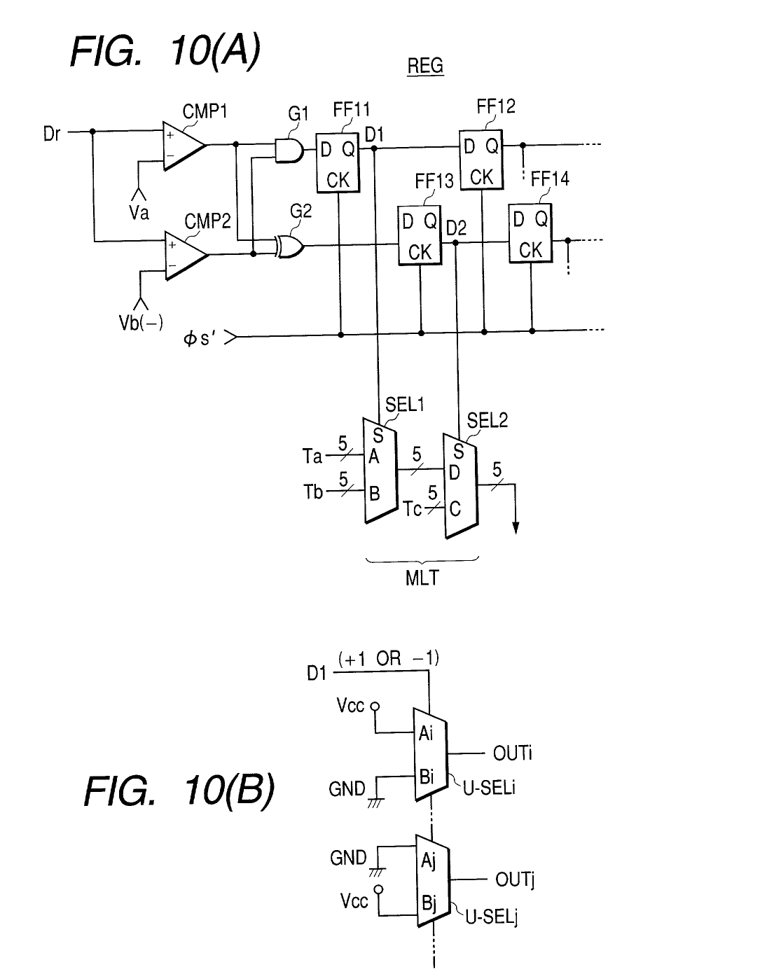

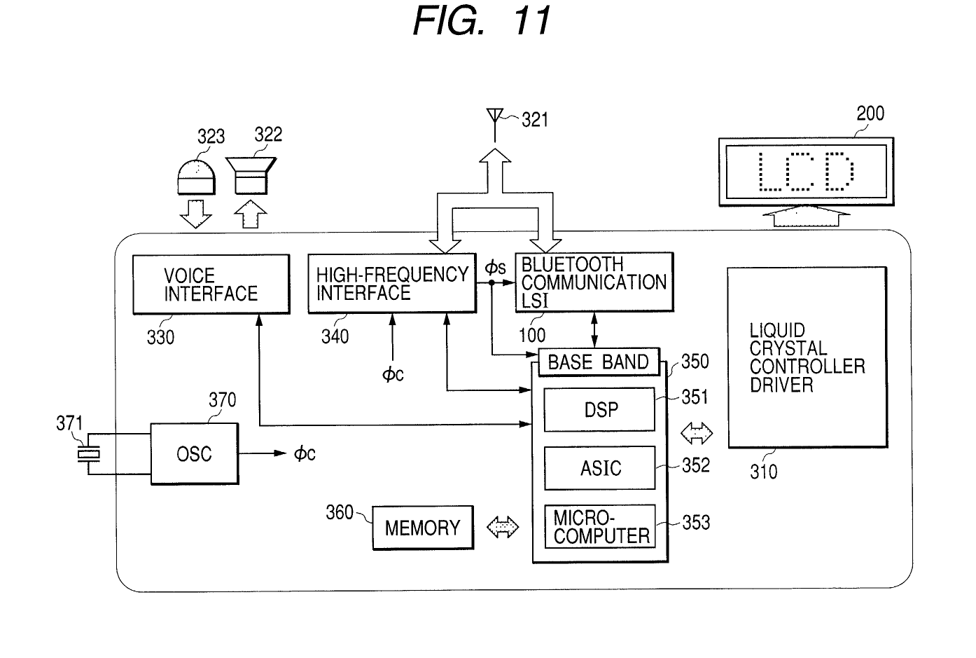

A circuit that determines whether a value calculated by the operation circuit 313 of FIG. 2 is “+1”, “−1”, or “0”, and converts the value into a 2-bit signal, and the multipliers MLT1 to MLT7 constituting the product-sum computing unit MAC shown in FIG. 3 that performs operations (so-called rounding) between 2-bit data captured into the input register part REG and tap coefficients can be realized by an example of hardware as shown in FIG. 10.

To be more specific, an output value Dr of the offset compensating circuit 31 is inputted to noninverting input terminals of two comparators CMP1 and CMP2, outputs of the comparators CMP1 and CMP2 are inputted to AND gate G1 to find a logical product of them, and inputted to exclusive OR gate G2 to find an exclusive logical add of them, output of the AND gate G1 is captured into flip-flop FF11 of the first stage of one shift register of the input register part REG, and output of the exclusive OR gate G2 is captured into flip-flop FF21 of the first stage of another shift register of the input register part REG.

A voltage Va that is lower than a voltage corresponding to “+1” and higher than a voltage corresponding to “0” is inputted to a noninverting input terminal of the comparator CMP1, and a voltage Vb(−) that is lower than a voltage corresponding to “0” and higher than a voltage corresponding to “−1” is inputted to a noninverting input terminal of the comparator CMP2. Thereby, when both outputs of the comparators CMP1 and CMP2 are at high level, it indicates that the output value Dr of the offset compensating circuit 31 is “+1”, so that the output of G1 is “1” and the output of G2 is “0”.

When both outputs of the comparators CMP1 and CMP2 are at low level, it indicates that the output value Dr of the offset compensating circuit 31 is “−1”, so that the output of G1 is “0” and the output of G2 is “0”. Furthermore, when the output of CMP1 is at low level and the output of CMP2 is at high level, it indicates that the output value Dr of the offset compensating circuit 31 is “0”, so that the output of G1 is “0” and the output of G2 is “1”. The outputs of the gates G1 and G2 are captured into the flip-flops F11 and F21 by a clock φs′ whose frequency is half that of the sampling clock φs, and are successively shifted.

The multiplier MLT can be configured with two selectors SEL1 and SEL2 as shown in FIG. 10. Data input terminals A and B of the selector SELL are respectively presented with tap coefficient Ta corresponding to data “+1” and tap coefficient Tb corresponding to data “−1”, latch data D1 of the flip-flop FF11 of the first shift register is inputted to a selection terminal S, and one of the tap coefficients Ta and Tb is outputted with the data D1 (+1 or −1).

On the other hand, data input terminals D and C of the selector SEL2 are respectively presented with the output of the selector SEL1 and tap coefficient Tc corresponding to data “0”, latch data D2 of the flip-flop FF21 of the second shift register is inputted to a selection terminal S, and output of the selector SEL1 or tap coefficient Tc is outputted by the data D2. The tap coefficients consist of 5 bits, one of which is used as a positive or negative sign. Bit coefficients Ta, Tb, and Tc take different values in each of the multipliers MLT1 to MLT5.

Furthermore, the selector SEL2 can, as shown in FIG. 10(B), be configured with five unit selectors U-SELi that each pull up one input terminal Ai to the power supply voltage Vcc and pull down another input terminal Bi to the ground terminal GND according to bits of inputted coefficients Ta and Tb, or five unit selectors U-SELj that each pull down one input terminal Aj to the ground terminal GND and pull up another input terminal Bj to the power supply voltage terminal Vcc. In this way, instead of a circuit in which input terminals of the selectors are fixed to Vcc or GND, registers holding filter coefficients may be provided so that the registers are switched by the selectors. Use of the registers has the advantage that filter coefficients can be made variable depending on the system. Furthermore, the number of stages of the input data register REG may be made variable.

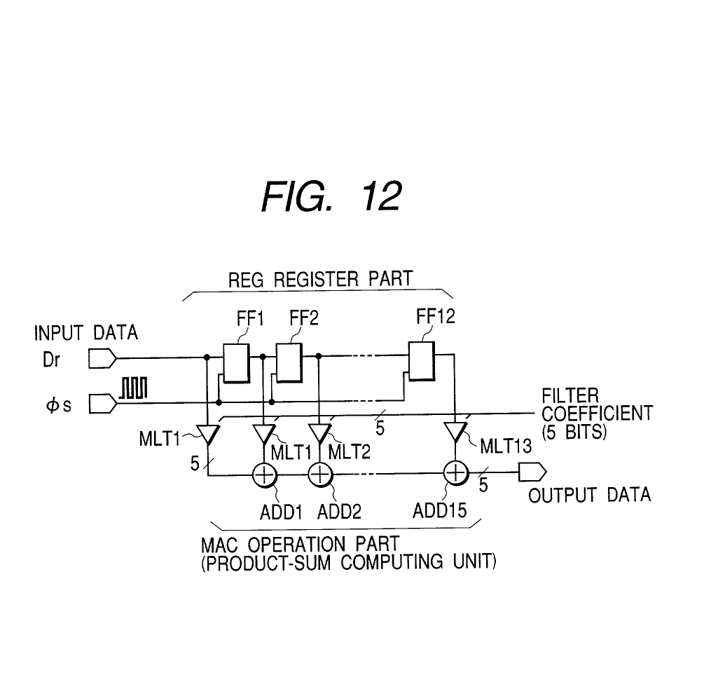

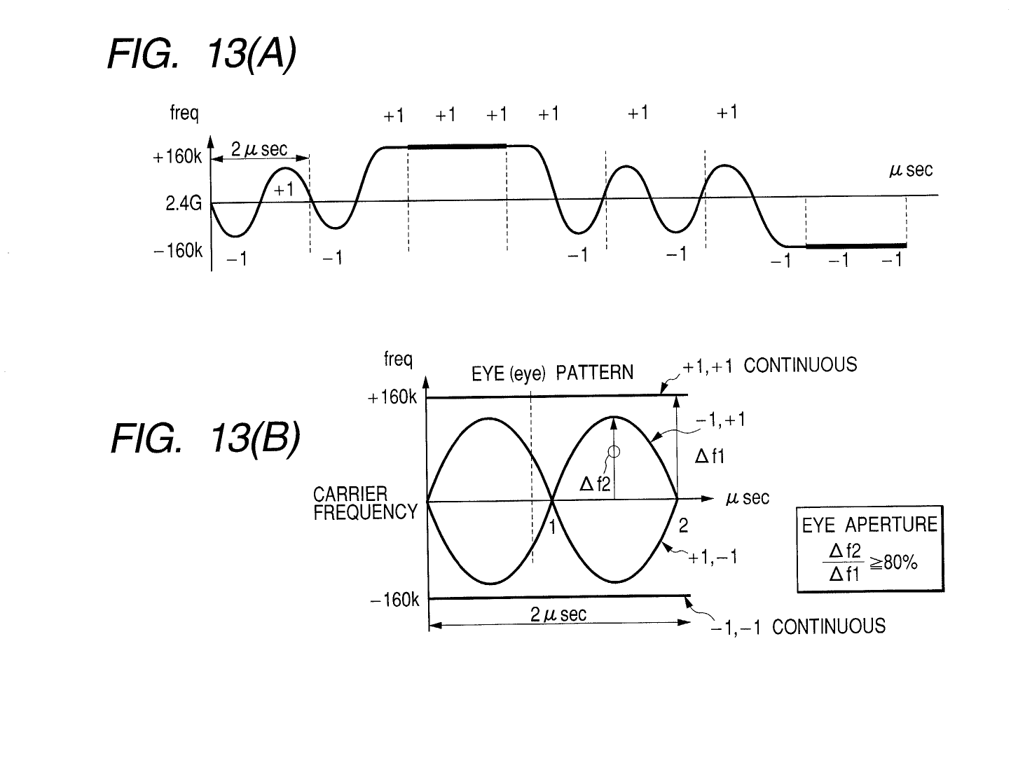

As seen from the embodiment of FIG. 10, if the present invention is applied, in comparison with a conventional digital filter shown in FIG. 12, a circuit is increased by the frequency offset compensating circuit 31, the comparators CMP1 and CMP2 evaluating the output of the divider 313, and the logical gates G1 and G2, while, although the flip-flops and the multipliers of the input register part REG are halved in terms of number of stages but unchanged in total number because of the two-row configuration, the number of adders is halved. As a result, although the scale of the whole circuit is unchanged, the circuit scale becomes slightly small because of the halved number of adders, and the operation frequencies of the filter circuit and the DA conversion circuit to perform DA conversion operation upon receipt of output of the filter can be approximately halved in comparison with conventional methods, with the result that power consumption of the digital control part of the DA conversion circuit can be halved.

FIG. 11 is a block diagram showing the overall configuration of a cellular telephone to which the wireless communication LSI of the above embodiment is applied. The cellular telephone of this embodiment comprises: a liquid crystal panel 200 as a display part; an antenna 321 for transmission and reception; a loudspeaker 322 for audio output; a microphone 323 for audio input; a liquid crystal control driver 310 that drives the liquid crystal panel 200 into display operation; an audio interface 330 through which signals of the loudspeaker 322 and the microphone are inputted and outputted; a high-frequency interface 340 through which cellular telephone communications are conducted by the GSM standard through the antenna 321; a wireless communication LSI 100, to which the present invention is applied, for conducting communications by the Bluetooth standard through the antenna 321; DSP (Digital Signal Processor) 351 for processing signals related to audio signals and transmission/reception signals; ASIC (Application Specific Integrated Circuits) 352 providing custom functions (user logic); a system control unit 353 comprising a microprocessor, microcomputer, or the like to control the whole apparatus, including display control; a memory 360 for storing data and programs; and an oscillating circuit (OSC) 370.

A so-called base band part 350 is composed of the DSP 351, ASIC 352, and the microcomputer 353 as a system control unit. Although only one base band part 350 is shown in the drawing, a base band part for the high-frequency interface 340 and a base band part for the wireless communication LSI 100 of the Bluetooth standard can be configured separately. In FIG. 11, 371 designates an oscillation element such as crystal oscillator, and the oscillating circuit 370 generates a clock of a frequency such as, e.g., 26 MHz. Crystal oscillators serving as a system clock source of the GSM system, which are distributed in large quantity and are available inexpensively, contribute to reduction in system costs.

The cellular telephone system of this embodiment includes the high-frequency interface 340 through which cellular telephone communications are conducted by the GSM standard, and the wireless communication LSI 100 of the above embodiment that conducts communications by the Bluetooth standard. Some cellular telephone systems of the present GSM standard use a 26-MHz system clock as an operation clock of a high-frequency LSI and supply a 13-MHz clock produced by halving the frequency of the 26-MHz system clock to the base band part. On the other hand, it is general that the wireless communication LSI 100 of the above embodiment that conducts communications by the Bluetooth standard also shares the system clock for operation when mounted in a GSM system.

Therefore, a system clock φc generated by the common oscillating circuit (OSC) 370 is supplied to the high-frequency interface 340 and a 13-MHz clock φc supplied from the high-frequency interface 340 to the base band part 350 is also supplied to the wireless communication LSI 100 of the above embodiment of the Bluetooth standard to drive it into operation. Alternatively, a 26-MHz clock generated in the oscillating circuit 370 is supplied to the high-frequency interface 340 of the GSM standard to drive it into operation, while a 13-MHz clock produced by the halving the frequency of the 26-MHz clock is supplied to the base band part 350 and the wireless communication LSI 100 of the Bluetooth standard to drive it into operation.

Thereby, a special oscillating circuit for the Bluetooth standard does not need to be provided and an LSI for wireless communications of the Bluetooth standard can be added to existing cellular telephones with an extremely small amount of hardware to be added. Thus mounting the wireless communication LSI 100 of the Bluetooth standard can provide the cellular telephone with diversified functions such as using the cellular telephone as a transceiver, outputting data received over the cellular telephone to a printer, and transmitting image data and audio data from a personal computer to the cellular telephone.

If the high-frequency interface 340 and the wireless communication LSI 100 of the above embodiment of the Bluetooth standard are mounted in a notebook size personal computer, hand-held PC, palmtop PC, and the like, data transmission with personal computers and peripheral equipment of the Bluetooth standard, and connection with the Internet are enabled.

The invention made by the inventor has been specifically described based on embodiments. It goes without saying that the present invention is not limited to the above embodiment and can be modified in various ways without departing from the spirit and scope of the present invention. For example, although, in the above embodiment, a description is made of a system that subjects data passing through a Gauss filter to frequency modulation before transmitting it, the present invention can also apply to a digital filter in a system that subjects data passing through a Gauss filter to phase modulation or amplitude modulation before transmitting it. The offset compensating circuit 31 of the embodiment shown in FIG. 2 drives delay flip-flops of the offset compensating circuit 31 into latch operation by a clock φs and a clock φs′ produced by halving the frequency of the clock φs by the frequency divider 33, and drives the digital FIR filter 32 into operation by the clock φs′. However, delay flip-flops of a portion driven into operation by the φs clock in the offset compensating circuit 31 may be driven into latch operation both on the rising edge and falling edge of clock to thereby drive the offset compensating circuit 31 and the digital FIR filter 32 into operation by an identical clock.

Moreover, depending on a phase relationship between clock f1 of the digital FIR filter and clock f2 of the offset compensating circuit, f1=Nf2 (N is an integer of 2 or greater) can be satisfied.

Although the foregoing description centers on the case where the invention made by the inventor applies to a Gauss filter used in a wireless communication system, which is an application field of the invention, the present invention, without being limited to it, can be used for general digital filters.

Effects obtained by typical ones of inventions disclosed in the present patent application will be briefly described below.

A filter that can achieve miniaturization and low power consumption at the same time can be formed without reducing operation precision, whereby a small-scale and low-power-consumption wireless communication system suitable for cellular electronic equipment can be realized.

What is claimed is:

1. A modulation semiconductor integrated circuit, comprising:
a digital filter that samples a digital transmission data signal an odd number of times for each two symbol cycles to perform predetermined operations;
a DA conversion circuit that subjects the output of the digital filter to DA conversion; and
a compensating circuit that inserts predetermined values different from two types of symbols to the input of the digital filter.

2. The modulation semiconductor integrated circuit according to claim 1, wherein the compensating circuit samples input data signals at a frequency N (N is an integer of 2 or greater) times a sampling frequency of the digital filter and outputs the average of two values sampled before and after.

3. The modulation semiconductor integrated circuit according to claim 2, wherein the compensating circuit comprises a delay means that samples input data signals at a frequency N times a sampling frequency of the digital filter and provides a delay of one cycle, an adder that adds a signal delayed by the delay means and an input signal, an operation means that halves the output of the adder, and a delay means for bringing an output of the operation means into line with the sampling frequency of the digital filter.

4. The modulation semiconductor integrated circuit according to claim 3, wherein the digital filter comprises an input shift register that successively samples and shifts outputs of the compensating circuit, plural first means that output a value corresponding to the product of data held at each stage of the register and a predetermined filter coefficient, and plural second means that successively add outputs of the first means and outputs the added value.

5. The modulation semiconductor integrated circuit according to claim 4, wherein the number of stages of the digital filter is seven.

6. The modulation semiconductor integrated circuit according to claim 4, wherein the filter coefficients are 5 bits.

7. The modulation semiconductor integrated circuit according to claim 4, further including an oscillating circuit whose oscillation frequency is controlled by the output of the DA conversion circuit, to subject an input data signal to frequency modulation and output a resulting signal.

8. The modulation semiconductor integrated circuit according to claim 7, wherein, in the case where a 2.4-GHz oscillation signal is used as a carrier frequency signal and outputted after frequency modulation in a range of ±160 kHz by an input data signal, a sampling frequency of the digital filter is set at approximately 6.5 MHz.

9. An electronic system comprising:
the modulation semiconductor integrated circuit of claim 1;
a wireless transmission means that converts signals to digital data and modulates the digital data for wireless transmission; and
an oscillating circuit that generates a clock signal required for operation of the wireless transmission means,
wherein a clock signal generated derivatively from a clock signal generated by the oscillating circuit is used as a sampling clock of the digital filter.

10. The electronic system of claim 9, wherein the wireless transmission means comprises a base band circuit that converts signals to digital data signals suitable for wireless communications, and a high-frequency modulation circuit that modulates digital data signals from the base band circuit to high-frequency signals and outputs the high-frequency signals, wherein a clock signal generated in the oscillating circuit is supplied to the high-frequency modulation circuit and a clock signal whose frequency is halved by the high-frequency modulation circuit is supplied to the base band circuit and the modulation semiconductor integrated circuit.
